(19) United States
(12) Patent Application Publication
(10) Pub. No.: US 2026/0025925 A1
(43) Pub. Date: Jan. 22, 2026

(54) PRINTED CIRCUIT BOARD VIA IMPEDANCE CONTROL

(71) Applicant: DELL PRODUCTS L.P., Round Rock, TX (US)

(72) Inventors: Pei-Ju Lin, Taoyuan District (TW); Ching-Huei Chen, Taoyuan City (TW); Han-Wei Yang, Luzhu (TW); Bhyrav Mutnury, Round Rock, TX (US)

(21) Appl. No.: 18/778,695

(22) Filed: Jul. 19, 2024

(51) Int. Cl. H05K 1/11; H05K 3/00; H05K 3/42

(52) U.S. Cl. CPC H05K 1/115; H05K 3/0047; H05K 3/42

(57) ABSTRACT

A printed circuit board, comprising a first conductive layer and a second conductive layer separated by an insulating layer and a via extending through the insulating layer and electrically coupling the first conductive layer and the second conductive layer. The via includes a sidewall of a dielectric material. In addition, the via is plated with a conductive material.

### FIELD OF THE DISCLOSURE

The present disclosure generally relates to information handling systems, and more particularly relates to a printed circuit board via impedance control.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A printed circuit board, comprising a first conductive layer and a second conductive layer separated by an insulating layer and a via extending through the insulating layer and electrically coupling the first conductive layer and the second conductive layer. The via includes a sidewall of a dielectric material. In addition, the via is plated with a conductive material.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an information handling system, according to an embodiment of the present disclosure;

FIGS. 2-5 are block diagrams of a system for printed circuit board via impedance control, according to an embodiment of the present disclosure;

FIG. 6 is a flowchart of a method for printed circuit board via impedance control, according to an embodiment of the present disclosure; and

FIG. 7 is a block diagram of a generalized information handling system, according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Printed circuit boards (PCBs) are typically included with hardware components of an information handling system. PCBs may include multiple layers wherein along each layer, conductive members are routed. Vias, which are disposed generally perpendicular to the PCB, are used to provide electrical connectivity between the traces on different layers of the PCB. Via impedance is a critical parameter in high-frequency PCB designs. Designing vias with controlled impedance helps to ensure that signals can propagate with minimal reflection. Parameters and considerations for controlling the via impedance include geometry, dielectric material, and layer stackup.

The geometry relates to its diameter, length, and shape of the via. A smaller diameter generally results in higher impedance while a longer length generally results in higher inductance which leads to higher impedance. Further, the shape of the via includes its antipad, wherein a larger antipad may result in reduced coupling capacitance, which can result in higher impedance. The dielectric constant of a PCB substrate material generally affects the speed of signal propagation. Generally, more layers in the layer stackup results in higher capacitance, which contributes to lower impedance. As such, the via impedance may vary depending on whether the inductance or the capacitance is dominant.

In addition, a PCB card generally includes short high-speed signal traces. To achieve a target impedance of these high-speed signal traces, expensive PCB material is generally used. Accordingly, because this implementation extends across the entire PCB, which results in a significant overall expense. Thus, there is a need for a cost-effective implementation to control the impedance of the PCB and its components, such as the via. Accordingly, the present disclosure provides a system and method for a two-time drilling technology to implement different dielectric materials for enhanced via impedance control.

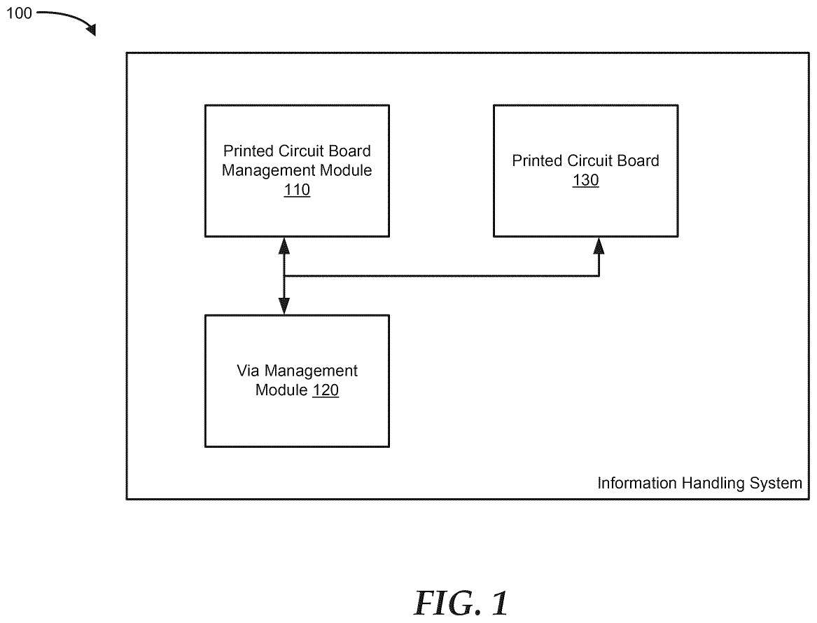

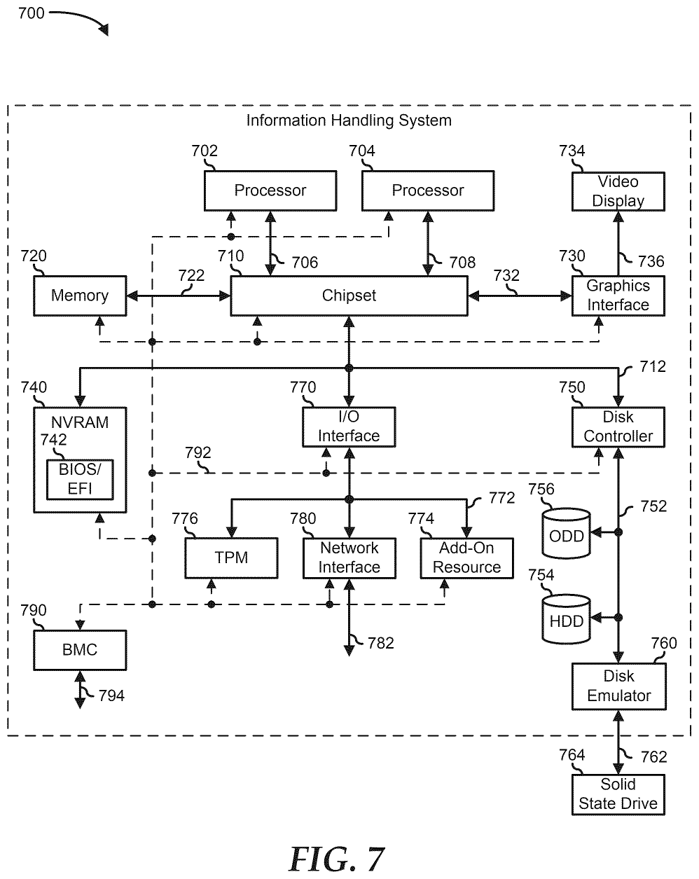

FIG. 1 illustrates a portion of an information handling system 100, which is similar to information handling system 700 of FIG. 7, according to an embodiment of the present disclosure. Information handling system 100 can include a PCB management module 110, a via management module 120, and a PCB 130. PCB management module 110 and via management module 120 can be included in a memory of information handling system 100, which is similar to memory 720 of FIG. 7. Further, PCB management module 110 and via management module 120 can be executed by a processor of information handling system 100, which is similar to processors 702 and/or 704 of FIG. 7. PCB management module 110 may be connected to via management module 120 and PCB 130. Any variety of connections between PCB management module 110, via management module 120, and PCB 130 are envisioned as falling within the scope of the present disclosure.

PCB designs adhere to a PCB aspect ratio, which is defined as a ratio of board thickness to the diameter of a drilled via. In determining the diameter of the drilled via, also referred to as a diameter of the drill hole of via 210, a minimum diameter of the drill hole may be considered based on the board thickness. The minimum diameter of the drill hole also determines the minimum size of the drill to be used for the via. For example, typically for a 62 mil PCB, the minimum drill size is 6 mil. However, for certain PCB designs where there is ample space; the size of the drill and accordingly the diameter of the via can be bigger.

In this example, PCB 130 may be drilled twice to create a sidewall of a dielectric material, which may allow for enhanced impedance control. The impedance of the via can be controlled according to the dielectric constant and thickness of the dielectric material of the sidewall. In line with this, PCB management module 110 may be configured to provide control of the via impedance associated with PCB 130 by determining the dielectric constant and the thickness of the dielectric material to achieve a target via impedance, according to specification within a target tolerance. PCB management module 110 may also determine the suitable dielectric material and/or size of the drill to be used for both drilling operations. PCB management module 110 may direct via management module 120 perform the operation based on such determination accordingly.

Via management module 120 may be configured to control back drilling of a via of PCB 130. The via can be back drilled with a drill size or diameter according to specification, The drill size for the backdrill is smaller than the diameter of the via to leave a sidewall. For example, the via can be back drilled to remove a portion of the dielectric material used to fill in the via. The back drilling may leave the sidewall of a certain width or thickness of the dielectric material. The thickness of the sidewall may be based on the dielectric material and the target via impedance. To achieve the desired thickness of the sidewall, the dielectric material can be removed by back drilling the via multiple times with increasing drill bit sizes.

Those of ordinary skill in the art will appreciate that the configuration, hardware, and/or software components of information handling system 100 may vary. For example, the illustrative components within information handling system 100 are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for continuity of the description.

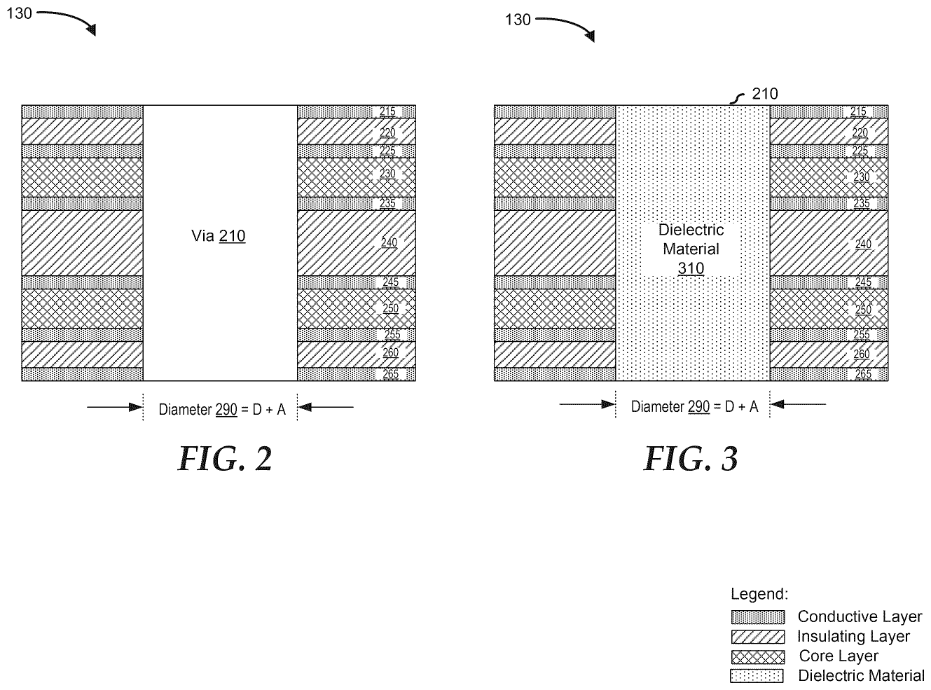

FIGS. 2, 3, 4, and 5 show simplified cross-section views of a portion of a PCB 130 configured via impedance control, according to an embodiment of the present disclosure. PCB 130 includes a plurality of conductive and insulating layers sandwiched together. In this example, PCB 130 includes conductive layers 215, 225, 235, 245, 255, and 265. PCB 130 also includes insulating layers 220, 240, and 260. In addition, PCB 130 includes core layers 230 and 250. Insulating layers 220, 240, and 260 are prepreg layers that are preferably fiberglass sheets or other dielectric materials for electrically isolating the conductive layers. The fiberglass sheet is preferably impregnated with resin or epoxy, which is a family of thermosetting resins used to form a chemical bond with metal. Core layers 230 and 250 can provide structural support for mounting components. The conductive layers, such as conductive layers 215, 225, 235, 245, 255, and 265, are typically made of copper foil, which is laminated to the insulation layer using heat and pressure. The copper foil is etched to form signal traces providing the conductive pathways for the electrical signals.

Holes or interconnect vias are usually drilled or punched into a PCB to provide a conductive path between certain traces on different layers. In this example, via 210 is disposed perpendicular to PCB 130 and is used to provide electrical connectivity between the traces on different layers of PCB 130. In particular, the via may extend through the insulating layer and electrically couple at least two conductive layers. A drill of a first drill size may be used to create a first drill hole for via 210 with a first diameter, wherein via 210 extends through insulating layers 220, 240, and 260. Via 210 may electrically couple at least two of conductive layers 215, 225, 235, 245, 255, and 265.

At this point, a first diameter of via 210 may be equal to the diameter of the first drill hole. The diameter of the first drill hole is also referred to herein as a diameter 290, wherein diameter 290 may be greater than or equal to a minimum via drill size “D” plus an allowance “A”. Minimum via drill size D may be based on current standards published by the Institute of Printed Circuits and based on thickness of PCB 130. In this example, for illustration purposes, we assume that the minimum via drill size D may be equal to 6 mils.

Typically, PCB manufacturers can maintain a via registration of around 2 mils per side. However, a via management module, such as via management module 120 of FIG. 1, may utilize camera-controlled drilling, also referred to as back drilling, to enhance precision and reduce the via registration to the assumption of 1 mil. This via registration tolerance may allow for a more accurate positioning of a second drill for back drilling via 210. The allowance A may be determined based on a desired minimum width of a via sidewall plus the manufacturing tolerance for via registration. Accordingly, the value of the allowance A may vary based on the desired minimum width of the dielectric material and the via registration tolerance. For illustration purposes, we assume that a specification desired minimum width is at least 3 mils thickness per side. We can also assume a 1 mil via registration per side for manufacturing tolerance as above. Thus, the allowance A may be equal to or greater than 8 mils. In this illustration, given the minimum via drill size D of 6 mils and the allowance of 8 mils, the size of the first drill may be equal to or greater than 14 mils.

FIG. 3 illustrates PCB 130 with via 210 filled in with a suitable dielectric material, such as a dielectric material 310. For example, if via 210 is a through via, then the dielectric material may reach both top and bottom surfaces of PCB 130. The dielectric material, also referred to as a plugging material, used to fill via 210 may have a dielectric constant based on a desired via impedance within a target tolerance. A manufacturer and/or PCB management module may specify impedance values of vias for pre-defined impedance classification, such as high, low, and/or nominal impedance. In addition, the manufacturer and/or the PCB management module may also determine a suitable dielectric material with a particular dielectric constant associated with each impedance classification. For example, a via classified as high impedance may be filled using a dielectric material with a dielectric constant that is greater than 4. A via classified as low impedance may be filled using a dielectric material with a dielectric constant that is between 1 through 3. Once via 210 is filled with dielectric material 310, the diameter of dielectric material 310 is similar to diameter 290.

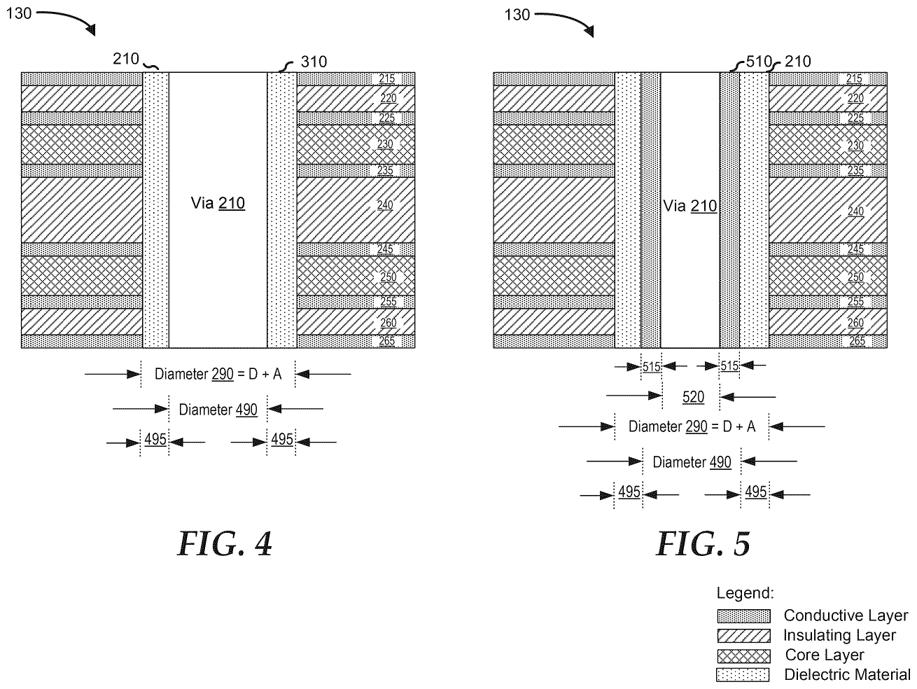

FIG. 4 illustrates PCB 130 with via 210 backdrilled using a drill bit of sufficient diameter to remove a portion of dielectric material 310. Via 210 may be drilled from the bottom or top side of PCB 130. The backdrill may have a diameter 490 which is less than diameter 290, leaving a sidewall composed of the dielectric material with a width 495 on each side. In one example, width 495 is around 3 mils as described above. Accordingly, in this example, diameter 490 may be equal to diameter 290 less 2*width 495. As such in this example, diameter 490 may be equal to or greater than 8 mils.

FIG. 5 illustrates PCB 130 with a plating of a conductive material on a surface of the sidewall of via 210 subsequent to being backdrilled. The plating may be referred to as a plating 510. In particular, the sidewall of via 210 may be electroplated with a conductive material, such as copper or any suitable material. Plating 510 may have a pre-defined thickness with a width 515 on each side of via 210. In one example, width 515 may be between 1 to 2 mils. Accordingly, a diameter 520 of via 210 may be equal to diameter 490 less 2*width 515. As such, diameter 490 may equal to or greater than 6 mils.

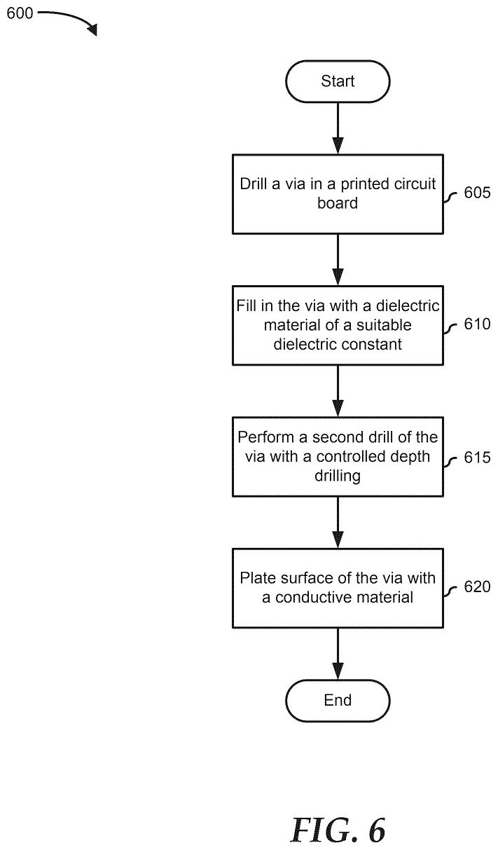

FIG. 6 illustrates a flowchart of a method 600 for a PCB via impedance control. Method 600 may be performed by any suitable component of information handling system 100 of FIG. 1, including but not limited to PCB management module 110 and via management module 120 of FIG. 1. While embodiments of the present disclosure are described in terms of the components of information handling system 100 of FIG. 1, it should be recognized that other components may be utilized to perform the described method. It will be readily appreciated that not every method step set forth in this flow diagram is always necessary and that certain steps of the methods may be combined, performed simultaneously, in a different order, or perhaps omitted, without varying from the scope of the disclosure. In addition, one of skill in the art will appreciate that this sequence diagram explains a typical example, which can be extended to applications or services in practice.

Method 600 typically starts at block 605 where a via may be drilled to a specified diameter as directed by a PCB management module and/or a via management module, as depicted in FIG. 2. At block 610, the via may be filled with a dielectric material of a suitable dielectric constant based on the desired impedance, as depicted in FIG. 3. The dielectric material may fill the length of the via. The dielectric material includes an electrically non-conductive epoxy, resin mixture, polyimide-based material, etc. The choice of the dielectric material and its thickness may help in ensuring that the via impedance meets specified requirements within a target tolerance. At block 615, the via may be backdrilled to a specified diameter, as depicted in FIG. 4. The back drilling may remove portions of the dielectric material while leaving a sidewall of a certain thickness or width. At block 620, the via may be plated with a conductive material to a certain thickness or width, such as depicted in FIG. 5. The choice of the conductive material and its thickness can be based on one or more factors that include the signal integrity, resistance, and capacitance of the PCB. Afterwards, the method ends.

FIG. 7 illustrates an embodiment of an information handling system 700 including processors 702 and 704, a chipset 710, a memory 720, a graphics adapter 730 connected to a video display 734, a non-volatile RAM (NVRAM) 740 that includes a basic input and output system/extensible firmware interface (BIOS/EFI) module 742, a disk controller 750, a hard disk drive (HDD) 754, an optical disk drive 756, a disk emulator 760 connected to a solid-state drive (SSD) 764, an input/output (I/O) interface 770 connected to an add-on resource 774 and a trusted platform module (TPM) 776, a network interface 780, and a baseboard management controller (BMC) 790. Processor 702 is connected to chipset 710 via processor interface 706, and processor 704 is connected to the chipset via processor interface 708. In a particular embodiment, processors 702 and 704 are connected together via a high-capacity coherent fabric, such as a HyperTransport link, a QuickPath Interconnect, or the like. Chipset 710 represents an integrated circuit or group of integrated circuits that manages the data flow between processors 702 and 704 and the other elements of information handling system 700. In a particular embodiment, chipset 710 represents a pair of integrated circuits, such as a northbridge component and a southbridge component. In another embodiment, some or all of the functions and features of chipset 710 are integrated with one or more of processors 702 and 704.

Memory 720 is connected to chipset 710 via a memory interface 722. An example of memory interface 722 includes a Double Data Rate (DDR) memory channel and memory 720 represents one or more DDR Dual In-Line Memory Modules (DIMMs). In a particular embodiment, memory interface 722 represents two or more DDR channels. In another embodiment, one or more of processors 702 and 704 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 720 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 730 is connected to chipset 710 via a graphics interface 732 and provides a video display output 736 to a video display 734. An example of a graphics interface 732 includes a Peripheral Component Interconnect-Express (PCIe) interface and graphics adapter 730 can include a four-lane (x4) PCIe adapter, an eight-lane (x8) PCIe adapter, a 16-lane (x16) PCIe adapter, or another configuration, as needed or desired. In a particular embodiment, graphics adapter 730 is provided down on a system PCB. Video display output 736 can include a Digital Video Interface (DVI), a High-Definition Multimedia Interface (HDMI), a DisplayPort interface, or the like, and video display 734 can include a monitor, a smart television, an embedded display such as a laptop computer display, or the like.

NVRAM 740, disk controller 750, and I/O interface 770 are connected to chipset 710 via an I/O channel 712. An example of I/O channel 712 includes one or more point-to-point PCIe links between chipset 710 and each of NVRAM 740, disk controller 750, and I/O interface 770. Chipset 710 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 740 includes BIOS/EFI module 742 that stores machine-executable code (BIOS/EFI code) that operates to detect the resources of information handling system 100, to provide drivers for the resources, to initialize the resources, and to provide common access mechanisms for the resources. The functions and features of BIOS/EFI module 742 will be further described below.

Disk controller 750 includes a disk interface 752 that connects the disc controller to a hard disk drive (HDD) 754, to an optical disk drive (ODD) 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an institute of electrical and electronics engineers (IEEE) 1394 (Firewire) interface, a proprietary interface, or a combination thereof. Alternatively, SSD 764 can be disposed within information handling system 700.

I/O interface 770 includes a peripheral interface 772 that connects the I/O interface to add-on resource 774, to TPM 776, and to network interface 780. Peripheral interface 772 can be the same type of interface as I/O channel 712 or can be a different type of interface. As such, I/O interface 770 extends the capacity of I/O channel 712 when peripheral interface 772 and the I/O channel are of the same type, and the I/O interface translates information from a format suitable to the I/O channel to a format suitable to the peripheral interface 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board, or add-in card disposed within information handling system 700, a device that is external to the information handling system, or a combination thereof.

Network interface 780 represents a network communication device disposed within information handling system 700, on a main circuit board of the information handling system, integrated onto another component such as chipset 710, in another suitable location, or a combination thereof. Network interface 780 includes a network channel 782 that provides an interface to devices that are external to information handling system 700. In a particular embodiment, network channel 782 is of a different type than peripheral interface 772 and network interface 780 translates information from a format suitable to the peripheral channel to a format suitable to external devices.

In a particular embodiment, network interface 780 includes a NIC or host bus adapter (HBA), and an example of network channel 782 includes an InfiniBand channel, a Fibre Channel, a Gigabit Ethernet channel, a proprietary channel architecture, or a combination thereof. In another embodiment, network interface 780 includes a wireless communication interface, and network channel 782 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 782 can be connected to an external network resource (not illustrated). The network resource can include another information handling system, a data storage system, another network, a grid management system, another suitable resource, or a combination thereof.

BMC 790 is connected to multiple elements of information handling system 700 via one or more management interface 792 to provide out of band monitoring, maintenance, and control of the elements of the information handling system. As such, BMC 790 represents a processing device different from processor 702 and processor 704, which provides various management functions for information handling system 700. For example, BMC 790 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 790 can vary considerably based on the type of information handling system. BMC 790 can operate in accordance with an Intelligent Platform Management Interface (IPMI). Examples of BMC 790 include an Integrated Dell® Remote Access Controller (iDRAC).

Management interface 792 represents one or more out-of-band communication interfaces between BMC 790 and the elements of information handling system 700, and can include an Inter-Integrated Circuit (I2C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 100, that is apart from the execution of code by processors 702 and 704 and procedures that are implemented on the information handling system in response to the executed code.

BMC 790 operates to monitor and maintain system firmware, such as code stored in BIOS/EFI module 742, option ROMs for graphics adapter 730, disk controller 750, add-on resource 774, network interface 780, or other elements of information handling system 700, as needed or desired. In particular, BMC 790 includes a network interface 794 that can be connected to a remote management system to receive firmware updates, as needed or desired. Here, BMC 790 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 790 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 790, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 790 is included on a main circuit board (such as a baseboard, a motherboard, or any combination thereof) of information handling system 700 or is integrated onto another element of the information handling system such as chipset 710, or another suitable element, as needed or desired. As such, BMC 790 can be part of an integrated circuit or a chipset within information handling system 700. An example of BMC 790 includes an iDRAC, or the like. BMC 790 may operate on a separate power plane from other resources in information handling system 700. Thus BMC 790 can communicate with the management system via network interface 794 while the resources of information handling system 700 are powered off. Here, information can be sent from the management system to BMC 790 and the information can be stored in a RAM or NVRAM associated with the BMC. Information stored in the RAM may be lost after power-down of the power plane for BMC 790, while information stored in the NVRAM may be saved through a power-down/power-up cycle of the power plane for the BMC.

Information handling system 700 can include additional components and additional buses, not shown for clarity. For example, information handling system 700 can include multiple processor cores, audio devices, and the like. While a particular arrangement of bus technologies and interconnections is illustrated for the purpose of example, one of skill will appreciate that the techniques disclosed herein are applicable to other system architectures. Information handling system 700 can include multiple central processing units (CPUs) and redundant bus controllers. One or more components can be integrated together. Information handling system 100 can include additional buses and bus protocols, for example, I2C and the like. Additional components of information handling system 100 can include one or more storage devices that can store machine-executable code, one or more communications ports for communicating with external devices, and various input and output (I/O) devices, such as a keyboard, a mouse, and a video display.

For purposes of this disclosure, information handling system 700 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 700 can include processing resources for executing machine-executable code, such as processor 702, a programmable logic array (PLA), an embedded device such as a System-on-a-Chip (SoC), or other control logic hardware. Information handling system 700 can also include one or more computer-readable media for storing machine-executable code, such as software or data.

Although FIG. 6 shows example blocks of method 600 in some implementations, method 600 may include additional blocks, fewer blocks, different blocks, or differently arranged blocks than those depicted in FIG. 6. Those skilled in the art will understand that the principles presented herein may be implemented in any suitably arranged processing system. Additionally, or alternatively, two or more of the blocks of method 600 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A method comprising:
drilling a via using a first drill size at a printed circuit board;
filling the via of the printed circuit board with a dielectric material;
removing a portion of the dielectric material by back drilling the via using a second drill size and leaving a sidewall of the dielectric material, wherein the second drill size is less than the first drill size; and
plating the sidewall of the via with a conductive material.

2. The method of claim 1, wherein the drilling of the via includes an allowance to accommodate the sidewall.

3. The method of claim 1, wherein the sidewall is of a pre-defined thickness.

4. The method of claim 1, wherein the dielectric material is chosen based on a dielectric constant.

5. The method of claim 1, wherein the sidewall is 3 mils in thickness.

6. The method of claim 1, wherein the plating of the via is to a pre-defined thickness.

7. The method of claim 1, wherein the conductive material is copper.

8. The method of claim 1, wherein the first drill size is equal to a minimum via drill size plus an allowance for the sidewall.

9. The method of claim 1, wherein the second drill size is equal to a minimum via drill size.

10. The method of claim 1, wherein the plating is between 1 to 2 mils in thickness.

11. A printed circuit board, comprising:
a first conductive layer and a second conductive layer separated by an insulating layer; and
a via extending through the insulating layer and electrically coupling the first conductive layer and the second conductive layer, wherein the via includes a sidewall of a dielectric material, and wherein the via is plated with a conductive material.

12. The printed circuit board of claim 11, wherein the sidewall is at least 3 mils in thickness.

13. The printed circuit board of claim 11, wherein the conductive material is between 1 to 2 mils in thickness.

14. The printed circuit board of claim 11, wherein the via is back drilled with a drill size equal to a minimum via drill size.

15. The printed circuit board of claim 11, wherein the dielectric material is chosen based on a dielectric constant.

16. An information handling system comprising:
a printed circuit board, comprising:
a first conductive layer and a second conductive layer separated by an insulating layer; and
a via extending through the insulating layer and electrically coupling the first conductive layer and the second conductive layer, wherein the via includes a sidewall of a dielectric material, and wherein the via is plated with a conductive material.

17. The information handling system of claim 16, wherein the sidewall is at least 3 mils in thickness.

18. The information handling system of claim 16, wherein the conductive material is between 1 to 2 mils in thickness.

19. The information handling system of claim 16, wherein the via is back drilled with a drill size equal to a minimum via drill size.

20. The information handling system of claim 16, wherein the dielectric material is chosen based on a dielectric constant.
